(19) United States
(12) Patent Application Publication
(10) Pub. No.: US 2024/0006858 A1
(43) Pub. Date: Jan. 4, 2024

(54) Wavelength Modulated Self-Mixing Interferometry Using Multi-Junction VCSEL Diodes

(71) Applicant: Apple Inc., Cupertino, CA (US)

(72) Inventors: Tong Chen, Fremont, CA (US); Pengfei Qiao, El Cerrito, CA (US); Fei Tan, San Jose, CA (US)

(21) Appl. No.: 18/142,812

(22) Filed: May 3, 2023

Related U.S. Application Data
(60) Provisional application No. 63/356,943, filed on Jun. 29, 2022.

(51) Int. Cl. H01S 5/42; H01S 5/183; H01S 5/026; H01S 5/343

(52) U.S. Cl. CPC H01S 5/423; H01S 5/18394; H01S 5/0262; H01S 5/34313

(57) ABSTRACT

Disclosed herein are self-mixing interferometry (SMI) sensors that include a multi-junction (MJ) vertical-cavity surface-emitting laser (VCSEL) diode that emits laser light in two directions, one direction being directed toward a receiving photodiode and another toward an object. Reflections from the object induce self-mixing interference within a resonance cavity of the MJ-VCSEL altering a wavelength of the emitted laser light. The SMI may infer distance and/or motion of the object from the alterations in the wavelength. In various embodiments, the MJ-VCSEL and photodiode are successively formed as a single unit upon a single substrate. In other embodiments, the MJ-VCSEL and the photodiode may be formed on separate wafers or chips that are then joined at a common interface surface. Arrays of combinations of MJ-VCSELs and associated photodiodes may be included in an SMI.

### CROSS-REFERENCE TO RELATED APPLICATION

This application is a nonprovisional and claims priority under 35 U.S.C. § 119(e) to U.S. Provisional Patent Application No. 63/356,943, filed Jun. 29, 2022, the contents of which are incorporated herein by reference as if fully disclosed herein.

### FIELD

The described embodiments generally relate to optical sensing and, more particularly, to optical sensing based on self-mixing interferometry (SMI).

### BACKGROUND

Electronic devices can be equipped with optical sensors. For example, optical sensors may be included in portable electronic devices such as mobile phones, tablet computers, laptop computers, cameras, portable music players, portable terminals, vehicle navigation systems, robot navigation systems, electronic watches, health or fitness tracking devices, and other portable or mobile devices. Optical sensors may also be included in devices that are semi-permanently located (or installed) at a single location (e.g., security cameras, doorbells, door locks, thermostats, refrigerators, or other appliances). Some of these electronic devices may include one or more input elements or surfaces, such as cameras, buttons, or touch screens, through which a user may enter commands or data via a touch, press, gesture, or image. The touch, press, gesture, or image may be detected by components of the electronic device (e.g., one or more optical sensors) that detect presence, distance, location, motion, topology, or other parameters. The same and/or other electronic devices may also or alternatively include one or more sensors, which sensors may sense proximity, distance, particle speed, or other parameters without receiving an intentional user input.

Some optical sensors may include a light source (e.g., a laser) that emits a beam of light, toward or through an input surface. Distance, location, motion, topology or other parameters of the input surface, or of an object on an opposite side of the input surface, may be inferred from reflections or backscatter of the emitted light, from the input surface and/or the object.

Some optical sensors may include a vertical-cavity surface-emitting laser (VCSEL) diode. A VCSEL diode may undergo self-mixing interference, in which reflections of its emitted laser light are received back into its lasing cavity. The self-mixing interference may induce a shift in a property of the laser light generated within the lasing cavity, such as wavelength, to a different state from what it would be in the absence of received reflections (“free emission”). In the case that the received reflections are from an input surface or object, the shift in the property may be correlated, for example, with the displacement, distance, motion, speed, or velocity of the input surface or object that caused the reflections.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

Described herein are various configurations of SMI sensors. Each SMI sensor may include a VCSEL diode and an associated photodiode (PD), such as a bulk light absorption photodiode or a resonance cavity photodiode (RCPD).

In some embodiments, an SMI sensor may include a first semiconductor photodiode formed on a substrate. The SMI sensor may also include a VCSEL that is vertically stacked with the semiconductor photodiode.

The VCSEL diode may have a resonance cavity containing a set of vertically stacked active regions, with adjacent active regions separated by a respective tunnel junction. The VCSEL diode may be configured to generate light within the resonance cavity, emit light toward an emission surface of the SMI sensor, self-mix the generated light with a reflection of the emitted light received into the resonance cavity, and to emit light toward the semiconductor photodiode. The semiconductor PD may be configured to produce a measurable electrical parameter related to the self-mixing.

In some embodiments, the active regions may each include multiple pairs of barrier layers alternating with quantum well layers. The n-type and p-type layer of a tunnel junction may be heavily doped. A diffraction grating may be positioned in an aperture of an oxide layer.

In some embodiments, an SMI sensor may include a multiple quantum well (MQW) photodiode formed on a substrate, and a VCSEL diode epitaxially formed on the first semiconductor layer vertically stacked on the MQW photodiode. The VCSEL diode may include a resonance cavity containing a set of vertically stacked active regions, with adjacent active region separated by a respective tunnel junction. The VCSEL diode may be configured to emit a light, such as a laser light, toward an emission surface of the SMI sensor, self-mix the generated light with a reflection of the emitted light received into the resonance cavity, and emit light toward the MQW photodiode. The MQW photodiode may be configured to produce a measurable electrical parameter related to the self-mixing.

The VCSEL diode of the SMI may include an emission side distributed Bragg reflector proximate to the emission surface of the SMI sensor and a base side distributed Bragg reflector interposed between the resonance cavity of the VCSEL diode and the MQW photodiode. The active regions each may include multiple barrier layers alternating with quantum well layers.

In some embodiments, an electronic sensing device is disclosed. The electronic sensing device includes an array of photodiodes formed on a substrate and an array of VCSEL diodes, vertically adjacent to the array of photodiodes at a common interface surface. The VCSEL diodes of the array of VCSEL diodes each include a respective resonance cavity, the respective resonance cavity containing a set of vertically stacked active regions, with adjacent active regions separated by a respective tunnel junction. The VCSEL diodes of the array of VCSEL diodes are each configured to generate light within the respective resonance cavity, emit light toward an emission surface of the electronic sensing device; self-mix the generated light with a reflection of the emitted light, and emit light toward the array of photodiodes. The photodiodes of the array of photodiodes are configured to produce a measurable electrical parameter related to the self-mixing.

There may be a first oxide layer formed between the resonance cavity and the emission surface of the electronic sensing device that includes a first aperture and a second oxide layer formed between the resonance cavity and the common interface surface.

The active regions of the VCSEL diodes of the array of VCSEL diodes may each include multiple barrier layers alternating with quantum well layers.

### BRIEF DESCRIPTION OF THE DRAWINGS

The disclosure will be readily understood by the following detailed description in conjunction with the accompanying drawings, wherein like reference numerals designate like structural elements.

FIG. 1 illustrates a system that includes a self-mixing interferometry sensor, according to an embodiment.

FIG. 2A illustrates a structure of a self-mixing interferometry sensor, according to an embodiment.

FIG. 2B illustrates one embodiment of operation of a self-mixing interferometry detector.

FIG. 2C is a graph of variation in power of laser light from a laser diode undergoing self-mixing interference with respect to the length of a feedback cavity.

FIG. 3 illustrates a structure of a single junction self-mixing interferometry sensor.

FIG. 4A illustrates a structure of a multi-junction self-mixing interferometry sensor, according to an embodiment.

FIG. 4B illustrates qualitative graphs of relationships between power and current in single junction and multi-junction self-mixing interferometry sensors, according to embodiments.

FIG. 4C illustrates qualitative graphs of relationships between power spectral density and frequency in single junction and multi-junction self-mixing interferometry sensors, according to embodiments.

FIG. 5 illustrates a structure of a self-mixing interferometry sensor that includes a multi-junction vertical-cavity surface-emitting laser diode, according to an embodiment.

FIG. 6 illustrates a structure of a self-mixing interferometry sensor formed with a first chip containing a multi-junction vertical-cavity surface-emitting laser diode joined to a second chip containing a photodiode, according to an embodiment.

FIG. 7 shows a plan view of a surface of a self-mixing interferometry sensor containing an array of multi-junction vertical-cavity surface-emitting laser diode diodes, according to an embodiment.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The embodiments described herein are directed to SMI sensors and devices (or just “SMI sensors”), such as may be used for touch or input sensors, proximity or particle sensors, or other types of sensors, and to their structures. Such SMI sensors may use one or more VCSEL diodes and associated photodiodes, such as resonance cavity photodiodes (RCPDs), that receive emitted laser light from the VCSEL. An electronic device may use such an SMI sensor as part of a system for detecting a displacement, distance, motion, speed, or velocity of an object (or “target”). Such an object may be a component of the electronic device, such as an input surface or touchpad, or the target may be external to the electronic device; for example, the SMI sensor may be part of an autofocus system of a camera and used to detect a distance to, or motion of, an external object. Hereinafter, for convenience, all such possible measured kinematic parameters of the target will be referred to simply as “distance or motion.”

In a VCSEL diode, in general, laser light is emitted from a resonance cavity containing at least one p-n junction. Reflections of the emitted laser light may be received back into the resonance cavity and induce self-mixing interference in which a property of the laser light, such as wavelength, is altered from the value it would have in the absence of receiving reflections. The alterations in the property can then be correlated with distance or motion of the object causing the reflections.

One way the altered property may be detected is by changes in one or more electrical properties of the VCSEL diode itself, such as voltage, current, power, etc. Alternatively, the altered emitted laser light may be received by a photodiode associated with the VCSEL diode, the photodiode having an output parameter related to the altered property of the self-mixed emitted laser light of the VCSEL diode.

In various embodiments described herein, a VCSEL diode may be structured to emit laser light in two directions, such as in opposite directions, from the resonance cavity. Laser light emitted in a first direction is directed toward an object or environment of interest, and laser light emitted in the second direction may be directed toward a photodiode. The alteration of the property of the laser light due to self-mixing with reflections from the object is then present in the laser light emitted in both directions. The photodiode receiving the self-mixed laser light emitted in the second direction may produce a measurable electrical parameter with a value related to the altered property of the laser light, from which a distance or motion of the object may be inferred.

In some embodiments described herein, a photodiode is formed in semiconductor base layers on a semiconductor substrate, such as by epitaxial deposition, and the VCSEL diode is subsequently formed on the semiconductor base layers above (opposite to the substrate) the photodiode. The VCSEL diode is operable to emit laser light both downward toward the photodiode and oppositely toward an object through an emission side of the SMI sensor. Various electrical connections may be formed in or on the substrate, the VCSEL diode, and/or the photodiode to, for example, bias the VCSEL diode, to receive signals from the photodiode, or other electrical signaling.

In some embodiments described herein, a photodiode is formed on (e.g., at or near a surface of) a first wafer or chip. A VCSEL diode is formed on a second wafer or chip so that it can emit light in two opposite directions from the second wafer. The first and second wafers or chips are then joined, such as by a flip-chip process, so that laser light emitted from the VCSEL diode in one direction can be received by the photodiode. The VCSEL diode may also emit laser light away from the first chip through an emission side of the SMI sensor toward a target. Reflections of that emitted light may be received into the VCSEL diode and induce self-mixing interference. The various electrical connections to the photodiode and the VCSEL diode may be formed on either or both wafers or chips. The photodiodes in the SMI sensors may have a bulk light absorption layer or a MQW layer.

In some embodiments, an SMI sensor may include a semiconductor wafer or chip having an array of VCSEL diodes. The semiconductor wafer may also include respective photodiodes for the VCSEL diodes. The VCSEL diodes may be configured to emit laser light both from the SMI sensor and toward the photodiodes. In other embodiments, An SMI sensor may be formed from a first semiconductor chip that includes an array of VCSEL diodes joined with a second semiconductor chip that includes an array of photodiodes.

A VCSEL diode may have its input current (or voltage) modulated to provide modulation of the emitted laser light. Such modulation of the emitted laser light may allow for inferring the distance and motion of a target.

In various embodiments, the SMI sensors may have VCSEL diodes with multiple tunnel junctions. Such multi-junction (MJ) VCSEL diodes may emit laser light with different properties than would be emitted by a comparable single junction (SJ) VCSEL diode operating at a similar current level. With multiple tunnel junctions, MJ-VCSEL diodes operate at increased voltage levels (compared to a similar SJ-VCSEL diode operating at a similar current level) and may provide multiple factors of increase of gain of, for example, output power. Also, the center frequency of the emitted laser light may be increased, which may improve signal-to-noise ratio (SNR) due to reduced 1/ƒ noise. Increased SNR and higher operating frequency may also allow for improved spatial resolution of targets by an SMI sensor making use of MJ-VCSEL diodes, due to possible increased range of modulation of the emitted laser light by the MJ-VCSEL diode.

Incorporating one or more MJ-VCSEL diodes and associated PDs in the same unit may improve performance of an SMI sensor, such as by faster signaling, and reduced complexity, among other reasons.

Further, although specific self-mixing interferometry devices are shown in the figures and described below, the embodiments described herein may be used with various electronic devices including, but not limited to, mobile phones, personal digital assistants, a time keeping device, a health monitoring device, a wearable electronic device, an input device (e.g., a stylus), a desktop computer, electronic glasses, etc. Although various electronic devices are mentioned, the self-mixing interferometry devices of the present disclosure may also be used in conjunction with other products and combined with various materials.

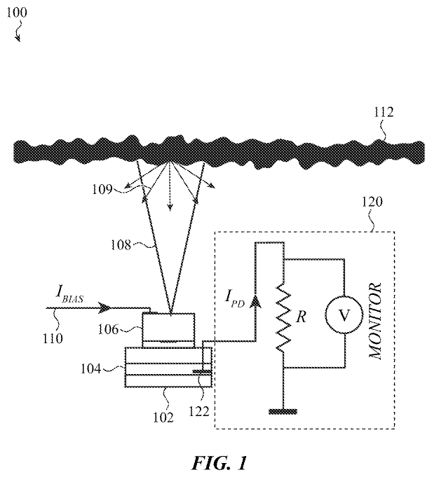

These and other embodiments are discussed below with reference to FIGS. 1-7. However, those skilled in the art will readily appreciate that the detailed description given herein with respect to these Figures is for explanatory purposes only and should not be construed as limiting.

FIG. 1 illustrates a configuration 100 in which an electronic device, containing a VCSEL diode 106, emits a laser light 108 toward an object 112. The VCSEL diode may be formed on a substrate 102, such as by epitaxial deposition (“epitaxially”) or other means. The VCSEL diode 106 and/or substrate 102 may be formed as part of a semiconductor wafer. The VCSEL diode 106 may emit the laser light 108 under a forward voltage bias (or just “forward bias”) of its diode structure. During such forward bias, a bias current I_{BIAS} 110, flows through the VCSEL diode 106. Charge carriers crossing the p-n junction of the VCSEL diode 106 may induce laser light emission from the VCSEL diode 106.

In various applications, the object 112 may be a surface of the electronic device, such as a touch pad surface of a smartphone or tablet computer. In other applications, the object 112 may be an object external to the electronic device, e.g., the electronic device may be a camera (either standalone or part of a smartphone or tablet computer, etc.) and the object is a distance from the camera. In such an application, the VCSEL diode 106 may be part of a range finding or autofocus feature of the camera.

There may be reflections 109 of the emitted laser light 108, which may travel in multiple directions from the object 112. Some of the reflections 109 may be received back into a lasing cavity of the VCSEL diode 106, causing self-mixing interference and altering a property of the emitted laser light 108 or of an electrical property of the VCSEL diode 106 itself. For example, associated detector 120 may receive signals from the VCSEL diode 106 that correlate with a distance or motion of the object 112.

In some configurations, the associated detector 120 may be electrically connected with an electrical component 122 connected with the VCSEL diode 106 and may detect changes in a junction voltage or current of the VCSEL diode 106 that are correlated with the self-mixing interference. For example, the electrical component 122 may be a transistor or other circuitry embedded in a semiconductor layer 104 of the substrate 102 that amplifies a voltage or current value across the junction of the VCSEL diode 106, with the amplified signal being received at the associated detector 120. Alternatively, in various embodiments described further below, the electrical component 122 may be a photodiode that receives emissions of laser light from the VCSEL diode 106 directed opposite from the emitted laser light 108. The photodiode may, for example, produce an output signal dependent on the wavelength of the laser light emitted by the VCSEL diode 106, from which the associated detector 120 can determine the self-mixing interference and infer the distance or motion of the object 112. In some embodiments, the photodiode may be formed in the semiconductor layer 104, such as epitaxially, that is formed on the substrate 102, with the VCSEL diode 106 then formed vertically above the semiconductor layer 104. Herein, “above” and “vertically above” will refer to a direction perpendicular to a layer or surface.

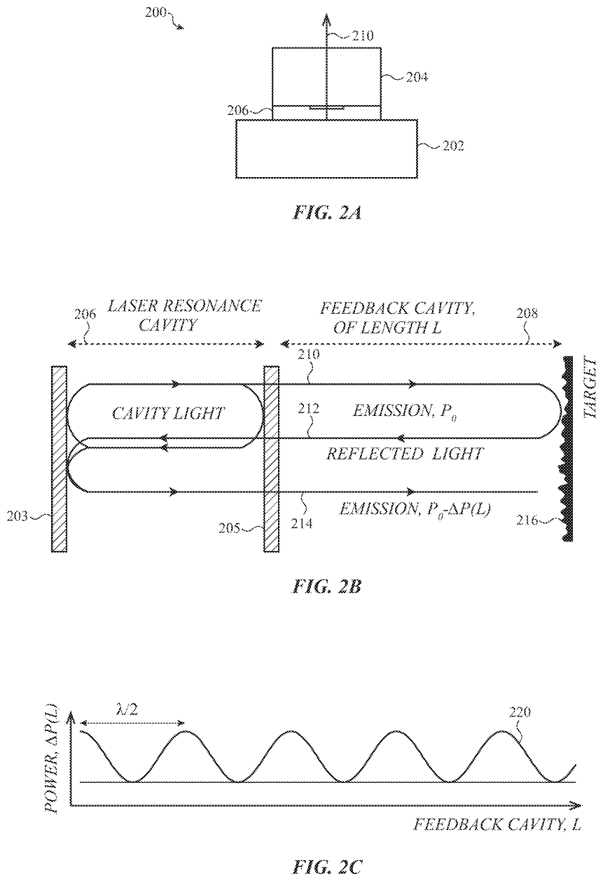

FIGS. 2A-C illustrate properties of self-mixing interference of emitted laser light in a laser diode. The explanations are intended only to describe various aspects of self-mixing interference needed to understand the disclosed embodiments. Other aspects of self-mixing interference will be clear to one skilled in the art.

FIGS. 2A-C illustrate an exemplary general configuration of a laser diode 200, such as the VCSEL diode 106 described herein, that may be used as part of an SMI sensor. The laser diode 200 may be formed on a base 202, which may be a semiconductor substrate, and contained in a housing or support structure 204. The laser diode 200 may contain a resonance cavity 206 from which laser light 210 is emitted, and which may include one or more semiconductor p-n junctions. In a laser, including laser diodes, an input energy source causes a gain material within a resonance cavity to emit light. As shown in FIG. 2B, mirrors 203 and 205 on opposite ends of the resonance cavity 206 feed the light back into the gain material to cause amplification of the light and to cause the light to become coherent and have a single predominant wavelength. An aperture in one of the mirrors allows transmission of the emitted laser light 210 (e.g., transmission toward an object or input surface, such as target 216).

In some laser diodes, distributed Bragg diffraction layers, on each side of the diode junction(s), may be formed as alternating semiconductor layers of high and low refractive indices, and may function as the mirrors 203 and 205. The resonance cavity 206 may contain the gain material, such as multiple doped layers of III-V semiconductors. Specific details of the semiconductor materials are presented herein for the various embodiments. The emitted laser light 210 can be emitted through the topmost layer or surface of the laser diode 200. In various embodiments described herein, the VCSEL diodes may also emit laser light through the bottom layer.

FIG. 2B shows a functional diagram of self-mixing interference (or also “optical feedback”) within a laser. In FIG. 2B, the laser resonance cavity 206 (or just “resonance cavity”) is shown reoriented so that the emitted laser light 210 is emitted to the right from the resonance cavity 206. The resonance cavity 206 has a fixed length, which may be established at manufacture. The emitted laser light 210 travels away from the resonance cavity 206 until it intersects or impinges on an input surface or another object, such as the object 112 described in relation to FIG. 1. The gap of distance L from the emission point through the mirror 205 of the emitted laser light 210 to the target 216 is termed the feedback cavity 208. The length L of the feedback cavity 208 is variable as the target 216 can move with respect to the laser diode 200.

The emitted laser light 210 is reflected back into the resonance cavity 206 from the target 216. The reflected light 212 enters the resonance cavity 206 to coherently interact with the original emitted laser light 210. This results in a new state illustrated with the altered emitted laser light 214. The altered emitted laser light 214 at the new state may have characteristics (e.g., a wavelength or power) that differ from what the emitted laser light 210 would have in the absence of reflection and self-mixing interference. Distance or motion of the target 216 may affect the length L and consequently may cause variation(s) of the wavelength of the altered emitted laser light 214, or of parameters (such as, but not limited to, power, voltage, or current) of the laser diode 200 itself. In one example, the altered emitted laser light has been altered from an initial value P0 by an amount, ΔP(L), that depends on length L of the feedback cavity 208. Measurements of such variations by an SMI sensor can be used to infer distance or motions of the target 216 from the laser diode 200.

FIG. 2C is a graph 220 showing the variation in power of the new emitted laser light 214 as a function of the length L of the feedback cavity 208, i.e., the distance from the emission point through the mirror 205 of the emitted laser light 210 to the target 216. The graph depicts a predominantly sinusoidal variation with a period of λ/2. Theoretical considerations imply that the variation is given by the proportionality relationship: ΔP ∝ cos(4πL/λ). This relationship generally holds in the absence of a strong specular reflection. In the case of such strong specular reflection, the cosine becomes distorted, i.e., higher harmonics are present in the relationship. However, the peak-to-peak separation stays at λ/2. For an initially stationary target 216, this relationship can be used to determine that a deflection has occurred. In conjunction with other techniques, such as counting of the completed number of periods, the range of the deflection may also be determined.

Though the graph 220 shows the variation in power of the new emitted laser light 214 as a function of the length L of the feedback cavity 208, similar results and/or graphs may hold for other interferometric properties of a VCSEL diode. Measurements of one or more such interferometric parameters by an SMI sensor can be used to infer distances or motions of the target 216 from the laser diode 200.

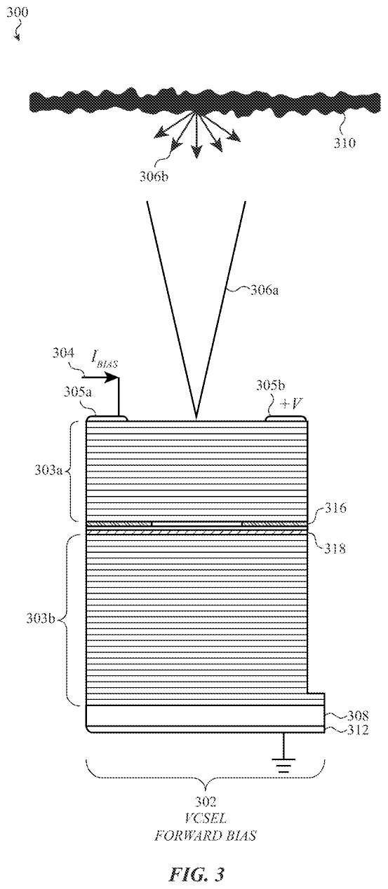

Further details of structures for VCSEL diodes that may be used in some of the embodiments are presented in relation to FIG. 3.

FIG. 3 illustrates a configuration 300 for a VCSEL diode 302 under forward bias and emitting a laser light 306a toward the object 310. Under the forward bias, a bias current 304, I_{BIAS}, flows into the VCSEL diode 302, with some or all of it returning to a ground layer or contact 312. As previously described, some reflections 306b from the object 310 of the emitted laser light 306a may be received back into the VCSEL diode 302 to induce self-mixing interference within a resonance cavity.

VCSEL diode 302 may include an emission side (or “top side”) distributed Bragg reflector 303a that functions as a first (or “emission side”) mirror of a laser structure. The emission side distributed Bragg reflector 303a may include a set of pairs of alternating materials having different refractive indices. Hereinafter, a distributed Bragg reflector is referred to as a “DBR.” Each such pair of alternating materials will be termed herein a Bragg pair. One or more of the materials in the emission side DBR 303a may be doped to be p-type and so form a part of the anode section of a p-n diode junction of the VCSEL diode 302. An exemplary pair of materials that may be used to form the emission side DBR 303a are aluminum gallium arsenide (AlGaAs) and gallium arsenide (GaAs).

VCSEL diode 302 may also include a base side DBR 303b that functions as a second (or “base side” or “bottom side”) mirror of a laser. The base side DBR 303b may also include a set of Bragg pairs of alternating materials having different refractive indices. One or more of the materials in the base side DBR 303b may be doped to be n-type and so form a part of the anode section of a p-n diode structure. An exemplary pair of materials that may be used to form the base side DBR 303b are aluminum arsenide and GaAs.

VCSEL diode 302 may include an active region 318 that functions in part as the lasing resonance cavity. In laser diodes, such as VCSEL diode 302, an active region may include one or more quantum wells. The active region 318 of VCSEL diode 302 may be adjacent to an oxide layer 316, having an aperture through which escapes the emitted laser light 306a.

The VCSEL diode 302 may be formed by epitaxial growth of the layers for each of the emission side and base side DBRs 303a, 303b, the active region 318 and the oxide layer 316, and possibly other layers. These various layers may be formed by epitaxial growth on a substrate layer 308, with the ground layer or contact 312 formed afterwards. Electrical supply contacts 305a, 305b may be formed on the outermost (i.e., emission side) layer of the VCSEL diode 302. While shown as separated in FIG. 3A, the electrical supply contacts 305a, 305b may be connected, such as to form, for example, a ring or horseshoe connection on the top side of the VCSEL diode 302.

The VCSEL diode 302 may alternatively be formed by epitaxial growth from a substrate starting with the layers for the emission side distributed Bragg reflector 303a. The substrate may then be separated, such as by etching or cleaving, and a flip chip process used to attach the VCSEL diode 302 to another substrate or circuit, so that the emission side DBR 303a is configured to emit laser light 306a.

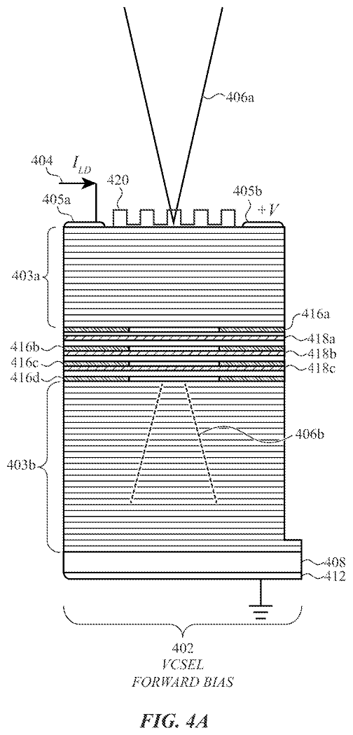

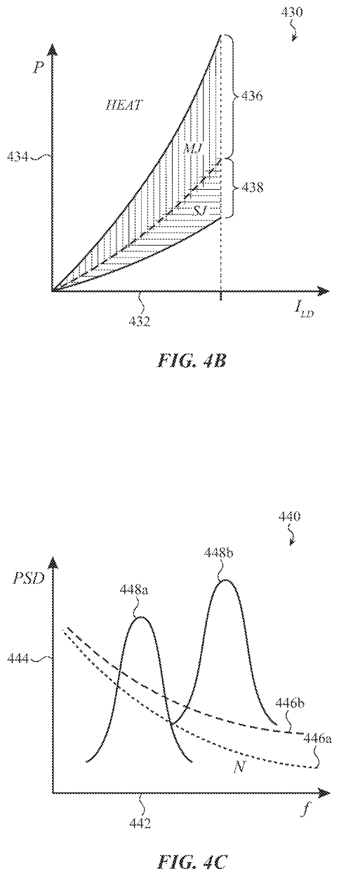

Certain types of VCSEL diodes that may be used in SMI sensors may be formed to have multiple p-n diode junctions, as described in relation to FIGS. 4A-C. As described in detail further below, VCSEL diodes having multiple p-n junctions may have different properties, such as emitted laser light wavelength, noise immunity, or output power that may be useful in an SMI sensor.

FIG. 4A illustrates a VCSEL diode 402 having a resonance cavity that contains multiple active regions and multiple p-n junctions formed in a vertical stack between an emission side distributed Bragg reflector 403a and a base side distributed Bragg reflector 403b. Such VCSEL diodes containing multiple p-n diode junctions are termed herein MJ-VCSEL diodes.

Many of the features of, and fabrication methods for, the MJ-VCSEL diode 402 may be as described herein for the single junction VCSEL diode 302. The emission side DBR 403a and base side DBR 403b may be as described for the DBRs 303a and 303b, respectively.

In some embodiments, the DBRs 403a and 403b may be formed by semiconductor epitaxy and either of the semiconductors GaAs, AlxGa1-xAs for (0<x≤1), or from other semiconductor materials. In other embodiments, the DBRs 403a and 403b may be formed from dielectric materials. Examples of such dielectrics include, but are not limited to, amorphous silicon (a-Si), SiO₂, SiO₂/Nb₂O₅, and SiO₂/Ta₂O₅. In yet other embodiments, the DBRs 403a and 403b may be formed as a hybrid of semiconductor materials and dielectric materials.

Between the DBRs 403a and 403b the MJ-VCSEL diode 402 may have multiple active regions that generate laser light when stimulated by a forward bias voltage. In the embodiment shown in FIG. 4A, there are three active regions: 418a, 418b, and 418c. It should be noted that in other embodiments, a MJ-VCSEL diode 402 may have two or more than three active regions. The active regions 418a-c are formed as a vertical sequence or stack between the DBRs 403a and 403b.

In the MJ-VCSEL diode 402, there is a first tunnel junction between the active regions 418a and 418b, and a second tunnel junction between active regions 418b and 418c. In MJ-VCSEL diodes having a different number of active regions, there is a tunnel junction between each successive pair of active regions. Optionally, the MJ-VCSEL diode 402 may also include one or more tunnel junctions at locations other than between a successive pair of the active regions 418a-c. The tunnel junctions of the MJ-VCSEL diode 402 may be either homogenous or heterogenous. Semiconductor materials that may be used for the tunnel junction's layers include GaAs, AlₓGa₁₋ₓAs, InₓGa₁₋ₓAs, InₓGa₁₋ₓP, GaAs₁₋ₓNₓ, InₓGa₁₋ₓAs_{y}P_{1-y} for (0<x≤1, 0<y<1), and others as known to one skilled in the art.

As an example, in one embodiment, each tunnel junction of MJ-VCSEL diode 402 may have a turn-on voltage (the forward bias voltage that initiates lasing) of approximately 1.3V, so the resulting turn-on voltage of the MJ-VCSEL diode 402 as a whole would become approximately 2.6V. The current, however, would remain as for a single tunnel junction, which in one embodiment would be 0.5 mA.

The tunnel junctions of the MJ-VCSEL diode 402 may be formed with both a heavily doped n-type layer and a heavily doped p-type layer. Examples of n-type dopants include, but are not limited to, Si, Te, and Se. Examples of p-type dopants include, but are not limited to, C, Zn, and Be. A heavily doped concentration value may be a doping concentration of at least 10¹⁸/cm³, and for some dopants may be as high as 10¹⁸/cm³.

The active regions 418a-c each contain multiple barrier layers and quantum well layers. The materials that may be used for the barrier layers of the active regions 418a-c include AlₓGa₁₋ₓAs (0<x≤1), GaAs₁₋ₓPₓ(0<x≤1), and others known to one skilled in the art. The materials that may be used for the quantum wells of the active regions 418a-c include: InₓGa₁₋ₓ As (0<x≤1), InₓGa₁₋ₓAs_{y}N_{1-y}, (0<x≤1, 0<y≤1), InₓGa₁₋ₓAs_{1-y-z}N_{y}Sb_{z}(0<x≤1, 0<y<1, 0<z<1, y+z<1), and others known to one skilled in the art.

The MJ-VCSEL diode 402 includes an emission side (or “top”) oxide layer 416a positioned between the topmost active region 418a and the emission side DBR 403a, the emission side oxide layer 416a including an aperture (or multiple apertures) through which the emitted laser light 406a may emerge. The MJ-VCSEL diode 402 includes also a base side (or “bottom”) oxide layer 416d positioned between the bottommost active region 418c and the base side DBR 403b, the base side oxide layer 416d including an aperture (or multiple apertures) through which the emitted laser light 406b may emerge. The MJ-VCSEL diode 402 may also include additional oxide layer 416b between active regions 418a and 418b, and an additional oxide layer 416c between active regions 418b and 418c. The additional oxide layers 416b and 416c each include an aperture (or multiple apertures) to allow generated to pass between the active regions 418a-c. The additional oxide layers 416b and 416c are optional: other embodiments of MJ-VCSEL diodes may have none, or more than one, oxide layer between successive active regions.

Windows or apertures in the oxide layers 416a-d may allow laser light generated in the active regions 418a-c to pass into each other and reinforce the generation of the laser light 406a emitted through the emission surface of the SMI sensor. A window in the bottom oxide layer 416d allows the generated laser light 406b to be emitted in a second direction, in this case through the base side DBR 403b.

The MJ-VCSEL diode 402 may have electrical contact(s) 405a and 405b positioned on or proximate to the emission side DBR 403a at which a bias voltage +V may be applied to cause the laser diode current I_{LD} 404 to flow into the MJ-VCSEL diode 402 to emit the laser light 406a and 406b. The electrical contacts 405a and 405b may be connected, such as in a ring around a window aperture through which laser light 406a is emitted. Such a window aperture may include a diffraction grating 420. The diffraction grating 420 may be formed as a GaAs/ALD grating (Gallium Arsenic, atomic layer deposition).

The MJ-VCSEL diode 402 may be joined at the base side DBR 403b to another semiconductor layer or substrate 408. A common ground connection 412 may be included in the semiconductor layer 408 to complete the electrical connections for the MJ-VCSEL diode 402.

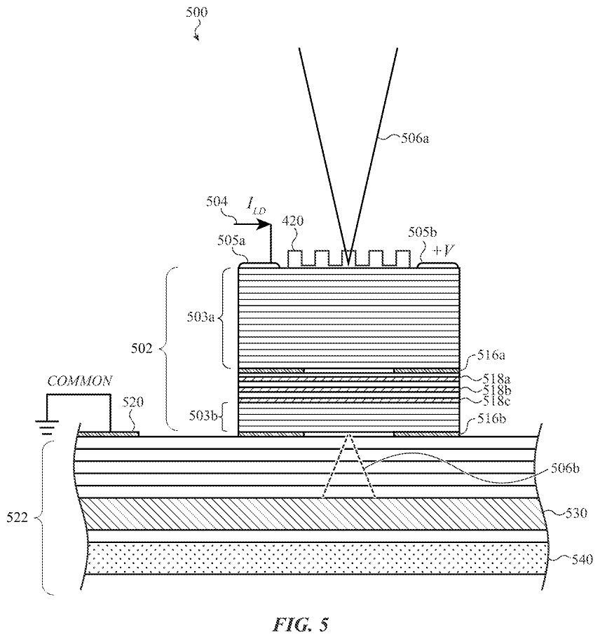

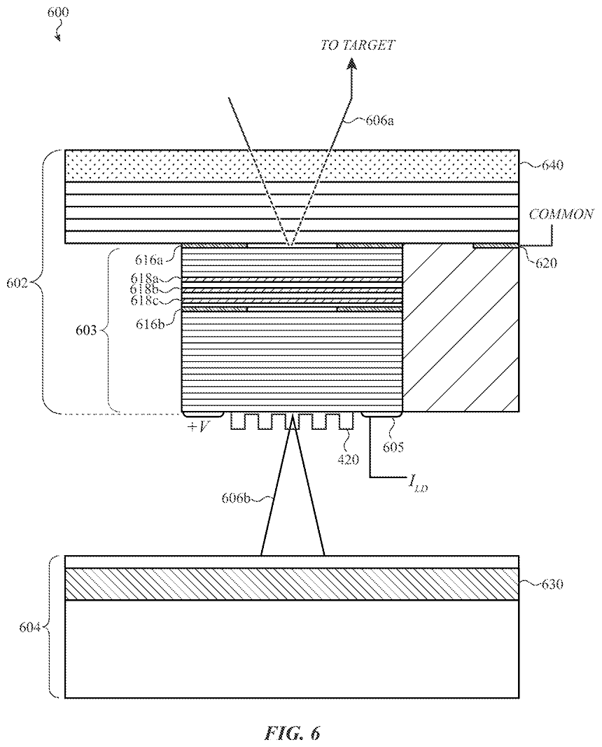

Some embodiments in which the semiconductor layer 408 includes a photodiode are presented in relation to FIG. 5. Other embodiments presented in relation to FIG. 6 describe an SMI sensor in which the MJ-VCSEL diode 402 is included in a first semiconductor chip that is joined to a second semiconductor chip that includes a photodiode.

FIG. 4B shows a qualitative comparative graph 430 of the power P, on vertical axis 434, versus the laser diode bias current I_{LD} on horizontal axis 432, for a single junction (SJ) VCSEL diode and for a MJ-VCSEL diode. The range of heat 438 produced by a SJ-VCSEL diode is less than the range of heat 436 produced by a MJ-VCSEL diode. The relationship ΔT=Rₜₕₑᵣₘ·ΔHeat describes the change in a diode temperature with respect to the change in heat produced for a given laser diode bias current I_{LD}. Together with the relationship Δλ=k_{DBR}·ΔT for the change in wavelength Δλ of the emitted laser light, this shows that a MJ-VCSEL diode can produce a greater wavelength modulation range for the emitted laser light for a given modulation range of the laser diode bias current I_{LD}.

In order to prevent excess heat generation in such a MJ-VCSEL diode, the duty cycle of a modulating current signal for forward biasing the MJ-VCSEL diode may be reduced compared to a modulating current signal for a SJ-VCSEL diode.

FIG. 4C shows a qualitative comparative graph 440 of the power spectral density (PSD) on the vertical axis 444 versus the frequency ƒ on the horizontal axis 442 of emitted laser light emitted from a single junction (SJ) VCSEL diode and from a MJ-VCSEL diode. Respective noise floors (N) 446a and 446b are shown for the SJ-VCSEL diode and from the MJ-VCSEL diode. The PSD of the MJ-VCSEL diode 448b has been shifted to have a higher center frequency compared to the PSD of the SJ-VCSEL diode 448a. Also, the output power is increased for the MJ-VCSEL diode with respect to a SJ-VCSEL diode. The formula for the center frequency is given by:

$${f}_{0} = \frac{Δ λ}{Δ I} \cdot \frac{Δ I}{Δ t} \cdot \frac{2 d}{λ}$$

for d the distance to the object or target from the emitting MJ-VCSEL diode. As Δλ is increased (as stated above), a MJ-VCSEL diode may achieve greater spatial resolution.

FIG. 5 illustrates a cross-section of at least a section of an SMI sensor 500 that includes an MJ-VCSEL diode 502 formed above photodiode (PD) 530. The PD 530 is shown formed within semiconductor base 522, which is formed on and includes the semiconductor substrate 540. In this embodiment of the MJ-VCSEL diode 502 formed together with PD 530, the MJ-VCSEL diode 502 is structured to be operable to emit a first laser light 506a in a first direction through an emission side surface of the SMI sensor 500, such as toward an object external to the SMI sensor 500. The MJ-VCSEL diode 502 is also structured to emit a second laser light 506b in a second direction into the semiconductor base 522, where it can be received by the PD 530.

The MJ-VCSEL diode 502 shown has electrical contacts 505a and 505b on or near the emission side surface of the SMI sensor 500 by which a bias voltage +V may be applied to allow the laser diode current I_{LD} to flow to the common (ground) contact 520. The electrical contacts 505a and 505b may be connected, such as in a ring structure.

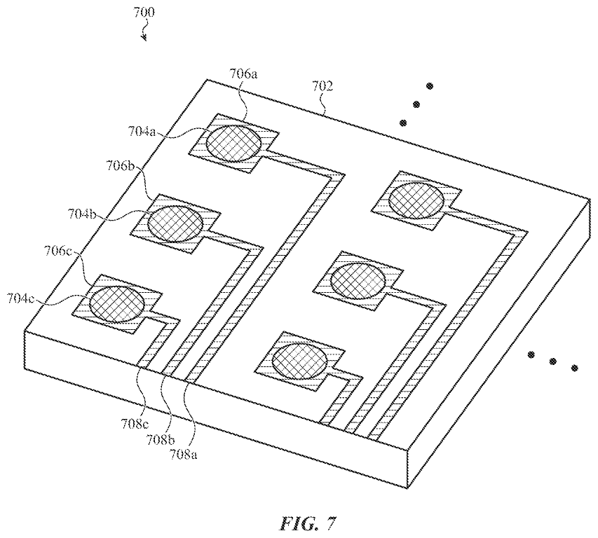

In the embodiment shown in FIG. 5, the MJ-VCSEL diode 502 extends above the top level of the layers of the semiconductor base 522. This structure may be formed, for example, by epitaxially forming the layers of the semiconductor base 522, subsequently forming the various semiconductor layers of the MJ-VCSEL diode 502, and then etching or otherwise removing sides from around the MJ-VCSEL diode 502. The common contact 520 may then be formed on a surface of the semiconductor base 522. However, this structure is not required. In another configuration, the semiconductor base 522 is epitaxially, or otherwise, formed on the semiconductor substrate 540, with the semiconductor layers for the MJ-VCSEL diode 502 extending across the semiconductor base 522 so that the MJ-VCSEL diode 502 is enclosed by material or structures on its lateral sides as well. Multiple MJ-VCSEL diodes may then be formed, such as in a planar array as shown in FIG. 7. Individual MJ-VCSEL diodes may be operationally isolated, such as by deep trench isolation wells, or similar structures.

In the embodiment shown in FIG. 5, the MJ-VCSEL diode 502 is formed with an emission side (or “upper”) DBR 503a proximate to the emission side surface of the SMI sensor 500 and a base (or “bottom”) side DBR 503b proximate to the semiconductor base 522. The DBRs 503a and 503b may be as described above in relation to FIG. 4A. A diffraction grating 420 may be positioned on the MJ-VCSEL diode 502 on or near the emission side DBR 503a proximate to the emission surface of the SMI sensor 500.

The MJ-VCSEL diode 502 has three active regions 518a, 518b, and 518c formed in a vertical stack. Also, there is a tunnel junction between active regions 518a and 518b, and another tunnel junction between active regions 518b and 518c. Each active region includes multiple barrier layers and MQW layers, such as described above in relation to FIG. 4A.

The MJ-VCSEL diode 502 has an emission side oxide layer 516a between the emission side DBR 503a and the vertical stack of active regions 518a-c, and a base side oxide layer 516b between the semiconductor base 522 and the vertical stack of active regions 518a-c. The oxide layers 516a-b are formed with apertures or openings that allow, respectively, the emitted laser lights 506a-b to be emitted. In related embodiments, the MJ-VCSEL diode 502 may include further oxide layers, such as between active regions.

FIG. 6 illustrates at least a section of an embodiment of an SMI sensor 600 that includes a VCSEL diode 603 formed on a first semiconductor wafer or chip 602 and a photodiode 630 formed on a second semiconductor wafer 604. Though shown separated for explanatory purposes, the first semiconductor wafer or chip 602 and the second semiconductor wafer 604 may be joined at a common interface surface, possibly with an intervening material layer. This embodiment allows for separate fabrication of the first and second semiconductor wafers 602 and 604, with subsequent joining, such as in a ‘flip-chip’ process. The VCSEL diode 603 is formed to emit laser light 606a and 606b in two opposite directions.

The VCSEL diode 603 is a MJ-VCSEL diode, such as discussed above in relation to FIG. 4A and FIG. 5. The MJ-VCSEL diode 603 may be fabricated on the base layers and/or substrate 640 of the first semiconductor wafer or chip 602 with processes and materials as described in reference to FIG. 4A. The MJ-VCSEL diode 603 has an emission or “top” side oxide layer 616a with an aperture to allow the emitted laser light 606a to be emitted from the SMI sensor 600 toward an object. After fabrication of the MJ-VCSEL diode 603 on the base layers and substrate 640 of the first semiconductor chip 602, some of the base layers and substrate 640 may be removed, such as by cleaving, etching, or another method. Such removal may provide adequate transparency for the emitted laser light 606a.

The MJ-VCSEL diode 603 has a base or “bottom” side oxide layer 616b with an aperture that allows emitted laser light 606b to be emitted across the common interface surface toward the second semiconductor chip 604 that includes a photodiode 630. In the embodiment shown, the diffraction grating 420 is located at or near the bottom surface of the MJ-VCSEL diode 603. The MJ-VCSEL diode 603 is biased from a voltage source V+ between the positive contact 605 and the common (ground) contact 620 to allow the laser diode current I_{LD} to flow.

The MJ-VCSEL diode 603 may contain three active regions 618a-c positioned as a vertical stack, have a first tunnel junction between active regions 618a and 618b, and have a second tunnel junction between active regions 618b and 618c. In alternative implementations of these embodiments, as discussed above, the MJ-VCSEL diode 603 may contain two, or more than three, active regions with a tunnel junction between each successive pair of active regions. Further, there may be additional oxide layers in the vertical stack between the top side oxide layer 616a and the bottom side oxide layer 616b.

The PD 630 may be a resonance cavity PD. The PD 630 may have multiple quantum wells. The PD 630 may be fabricated of the materials discussed previously.

FIG. 7 shows a perspective view 700 of a semiconductor chip 702 that includes an array of VCSEL diodes 706a-c. Though shown as a rectangular array, the multitude of VCSEL diodes 706a-c may be arranged in alternate patterns. The VCSEL diodes 706a-c may be implemented with respective diffraction gratings 704a-c positioned in aperture windows through which the VCSEL diodes 706a-c emit respective laser light. Some or all of the VCSEL diodes 706a-c may be multiple junction VCSELs as described above.

Each of VCSEL diodes 706a-c may have respective electrical control connections 708a-c. The electrical control connections 708a-c may, for example, supply the bias current or voltage to the respective VCSEL diodes 706a-c. One skilled in the art will recognize that though each of the VCSEL diodes 706a-c has an individual respective control connection, alternatively a single control connection may connect to multiple VCSELs on the semiconductor chip 702.

In some embodiments, the semiconductor chip 702 may be included in an SMI sensor, and the VCSEL diodes 706a-c may transmit laser light through the diffraction gratings 704a-c vertically upward toward a target or object external to the SMI sensor. Such embodiments may further include respective photodiodes (not shown) below the VCSEL diodes 706a-c within the semiconductor chip 702, with VCSEL diodes 706a-c operable to emit laser light also toward the photodiodes as well as through the diffraction gratings 704a-c, as described previously in relation at least to FIG. 5.

In alternative embodiments, the semiconductor chip 702 with its array of VCSEL diodes 706a-c may be used as a component in a ‘flip chip’ configuration of an SMI, as discussed in relation to FIG. 6. In such embodiments, the VCSEL diodes 706a-c may emit laser light through the diffraction gratings 704a-c toward photodiodes implemented on another semiconductor chip joined to the semiconductor chip 702.

In these, or other, families of embodiments, the VCSEL diodes 706a-c may be triggered (biased to emit laser light) either concurrently or in a staggered pattern. A concurrent triggering operation may allow for improved sensing of distance or motion of the external object. For example, statistical analyses may be used, such as averaging of, or discarding of extreme outliers of, values from a set of values of distance or motion of the object inferred from the VCSEL diodes 706a-c. A sequential, staggered, or non-concurrent triggering may allow for anticipation of motion, such as of a finger depressing a touchpad, so that not all of VCSEL diodes 706a-c need be triggered.

Other examples and implementations are within the scope and spirit of the disclosure and appended claims. For example, features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C). Further, the term “exemplary” does not mean that the described example is preferred or better than other examples.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. A self-mixing interferometry (SMI) sensor, comprising:
a semiconductor photodiode formed a substrate; and
a vertical-cavity surface-emitting laser (VCSEL) diode vertically stacked on the semiconductor photodiode; wherein:
the VCSEL diode includes a resonance cavity containing a set of vertically stacked active regions, with adjacent active regions separated by a respective tunnel junction;
the VCSEL diode is configured to generate light within the resonance cavity, emit light toward an emission surface of the SMI sensor, self-mix the generated light with a reflection of the emitted light received into the resonance cavity, and emit light toward the semiconductor photodiode; and
the semiconductor photodiode is configured to produce a measurable electrical parameter related to the self-mixing.

2. The SMI sensor of claim 1, wherein the set of vertically stacked active regions include barrier layers alternating with quantum well layers.

3. The SMI sensor of claim 1, wherein a tunnel junction separating a first active region and a second active region of the set of vertically stacked active regions includes a heavily doped p-type semiconductor layer and a heavily doped n-type semiconductor layer.

4. The SMI sensor of claim 3, with at least one of the following properties:
the heavily doped p-type semiconductor layer of the tunnel junction has a first doping concentration at least 10¹⁸/cm³; and
the heavily doped n-type semiconductor layer of the tunnel junction has a second doping concentration at least 10¹⁸/cm³.

5. The SMI sensor of claim 1, wherein the VCSEL diode includes:
a first oxide layer interposed between the resonance cavity and the emission surface, and
a second oxide layer interposed between the resonance cavity and the semiconductor photodiode, the first oxide layer having a first aperture and the second oxide layer having a second aperture.

6. The SMI sensor of claim 5, wherein the VCSEL diode includes an additional oxide layer between at least one adjacent pair of active regions.

7. The SMI sensor of claim 5, further comprising a diffraction grating within the first aperture of the first oxide layer.

8. The SMI sensor of claim 7, wherein the diffraction grating causes the emitted light of the VCSEL diode to have a predominant transverse mode electric field.

9. The SMI sensor of claim 1, wherein the semiconductor photodiode is a resonance cavity photodiode (RCPD), wherein the RCPD includes multiple quantum wells.

10. The SMI sensor of claim 1, wherein:
the substrate is a first substrate;
the VCSEL diode is formed on a second substrate;
the first substrate is stacked on the second substrate so that the light emitted by the VCSEL diode toward the emission surface of the SMI sensor is directed toward the semiconductor photodiode.

11. A self-mixing interferometry (SMI) sensor, comprising:
a multiple quantum well (MQW) photodiode formed on a substrate; and
a vertical-cavity surface-emitting laser (VCSEL) diode vertically stacked on the MQW photodiode; wherein:
the VCSEL diode includes a resonance cavity containing a set of vertically stacked active regions, with adjacent active regions separated by a respective tunnel junction;
the VCSEL diode is configured to generate light within the resonance cavity, emit light toward an emission surface of the SMI sensor, self-mix the generated light with a reflection of the emitted light received into the resonance cavity, and emit light toward the MQW photodiode; and
the MQW photodiode is configured to produce a measurable electrical parameter related to the self-mixing.

12. The SMI sensor of claim 11, wherein:
the VCSEL diode includes:
an emission side distributed Bragg reflector proximate to the emission surface of the SMI sensor; and
a base side distributed Bragg reflector interposed between the resonance cavity of the VCSEL diode and the MQW photodiode.

13. The SMI sensor of claim 12, further comprising:
an oxide layer between the emission side distributed Bragg reflector and the resonance cavity; and
a diffraction grating positioned between the emission side distributed Bragg reflector and the emission surface of the SMI sensor;
wherein the diffraction grating causes the emitted light of the VCSEL diode to have a predominant transverse mode electric field.

14. The SMI sensor of claim 12, wherein a tunnel junction separating a first active region and a second active region of the set of vertically stacked active regions includes:
a heavily doped p-type semiconductor layer; and
a heavily doped n-type semiconductor layer; wherein a doping concentration of the p-type semiconductor layer and a doping concentration of the n-type semiconductor layer are at least 10¹⁸/cm³.

15. The SMI sensor of claim 11, wherein quantum wells of the MQW photodiode are formed from Indium Gallium Arsenide.

16. The SMI sensor of claim 11, wherein the vertically stacked active regions each include multiple barrier layers alternating with quantum well layers.

17. An electronic sensing device, including:
an array of photodiodes formed on a substrate; and
an array of vertical-cavity surface-emitting laser (VCSEL) diodes; vertically adjacent to the array of photodiodes at a common interface surface; wherein:
the VCSEL diodes of the array of VCSEL diodes each include a respective resonance cavity, the respective resonance cavity containing a set of vertically stacked active regions, with adjacent active regions separated by a respective tunnel junction;
the VCSEL diodes of the array of VCSEL diodes are each configured to generate light within the respective resonance cavity, emit light toward an emission surface of the electronic sensing device; self-mix the generated light with a reflection of the emitted light, and emit light toward the array of photodiodes; and
the photodiodes of the array of photodiodes are configured to produce a respective measurable electrical parameter related to the self-mixing.

18. The electronic sensing device of claim 17, wherein the vertically stacked active regions each include multiple barrier layers alternating with quantum well layers.

19. The electronic sensing device of claim 18, further comprising:
a first oxide layer formed between the resonance cavity and the emission surface of the electronic sensing device and including a first aperture; and
a second oxide layer formed between the resonance cavity and including a second aperture.

20. The electronic sensing device of claim 18, wherein at least one photodiode of the array of photodiodes includes multiple quantum wells.
